(19) United States
(12) Patent Application Publication
(10) Pub. No.: US 2012/0018802 A1
(43) Pub. Date: Jan. 26, 2012

(54) Ultra-low-cost three mask layers trench MOSFET and method of manufacture

(76) Inventors: Wei Liu, Suzhou (CN); Fan Wang, Suzhou (CN); Yichuan Cheng, Suzhou (CN)

(21) Appl. No.: 12/841,036

(22) Filed: Jul. 21, 2010

(51) Int. Cl. H01L 29/78; H01L 21/336

(52) U.S. Cl. 257/334; 438/270; 257/E29.262; 257/E21.41

(57) ABSTRACT

An ultra-low-cost three mask layers trench MOSFET and its method of manufacture, wherein the method includes posting a uniform-covering dielectric layer deposition, and then the topography of trenches with different open size is quite different, wherein the smaller open size trench is fully filled, while only bottom and sidewall are covered for the bigger one. After a patterned dry etch process, the bottom of the bigger trench is opened with dielectric spacer left on sidewall, and the smaller one is still filled with dielectric material. The remained dielectric material is used as masks for following N+ source implantation and/or P-body implantation. A self-aligned source contact process is performed using the remained dielectric material in the trench as hard mask, so the limitation coming from source contact trench to gate trench mis-alignment during photo process is eliminated. Therefore, the much higher cell density, means high device performance, could be achieved.

### BACKGROUND OF THE PRESENT INVENTION

1. Field of Invention

The present invention relates to a high power MOS device and method of manufacture, and more particularly to an ultra-low-cost three mask layers trench MOSFET and its method of manufacture.

2. Description of Related Arts

Trench MOSFET devices are widely used in power application. They function as switches connecting power and load. A trench MOSFET is a vertical transistor in which the channel is formed vertically and the gate is formed in a trench extending between the source and drain. The voltage rating of the trench MOSFET is a function of the doping and thickness of an epitaxial layer, while the current rating is a function of the channel width. The trench is formed in a cellular structure. High-current capability is obtained by connecting many cells together in parallel.

A higher cell density leads to bigger channel width, and then when the trench MOSFET is in on-state, less heat generation and power loss are the benefits, means high performance. And also, higher cell density means more chips are fabricated within one silicon wafer, lower cost per chip could be expected.

The conventional N-channel trench MOSFET process is illustrated in FIG. 1A to FIG. 1E.

Referring to FIG. 1A, an N+ substrate 11 is prepared as drain of the MOSFET, and an N type epi-layer 12 is grown on the substrate 11. An oxide layer is grown on the epi-layer 12. Then the 1^{st} mask is used to pattern a P-type implantation. Posting a thermal process, the P-body region 13 is formed into the epi-layer 12.

Referring to FIG. 1B, an oxide layer is formed on top of the epi-layer 12 acting as hard mask. Then the 2^{nd} mask is used. Posting a dry etch process, a number of trenches are formed into the epi-layer 12, with a bigger depth than the P-body region 13. The trenches with small open size 14 illustrate MOSFET chip cellular structure gate. The trench with big open size 15 represents the gate contact region, which is on the edge of the chip surrounding the cells. The trenches with small open size 14 are connected with the trench with big open size 15, thus forming the interconnecting trench grids.

Referring to FIG. 1C, posting the oxide hard mask layer removed, a gate oxide layer 16 is grown. Then an N+ polysilicon deposition and dry etch are performed, thereby forming the trench gate 17 and gate contact region 18. Then the 3^{rd} mask is used and posting an N-type implantation, the N+ source region 19 inside the P-body region 13 is formed.

Referring to FIG. 1D, an oxide layer is deposited on the entire structure, then the 4^{th} contact mask, is used to etch the oxide and silicon. The contact trench 20 has a bigger depth than the N+ source region 19. A P-type implantation is carried out to reinforce the P-type doping concentration of a region below the contact trench 20 and within the P-body region 13, thus forming a P+ heavy body region 21.

Referring to FIG. 1E, a Ti glue layer 22 and a TiN barrier layer 23 are formed on the entire structure. Then Tungsten deposition and dry etch are performed to form the tungsten contact plug 24. Metal layer is deposited, and then the 5^{th} mask is used to pattern the source and gate electrodes. Drain electrode is formed on the rear face of the substrate and not illustrated in the drawings.

It is obvious that five mask layers are used for preparing P-body, trench, N+ source, contact, and metal respectively in the conventional N-channel trench MOSFET process. In general, every mask increases about 15% of the cost. Therefore, the more the mask is, the higher the cost becomes. U.S. Pat. Nos. 6,204,533, 6,211,018, 7,592,650, and 7078296, give different approaches to get the high density, however, similar mask layers as conventional process or complicated processes are involved.

### SUMMARY OF THE PRESENT INVENTION

An object of the present invention is to provide an ultra-low-cost three mask layers trench MOSFET and its method of manufacture, which reduces the mask layers, thus significantly reducing the manufacturing cost.

Another object of the present invention is to provide ultra-low-cost three mask layers trench MOSFET and its method of manufacture, which is capable of increasing the cell density, thus obtaining a high device performance.

Accordingly, in order to accomplish the above objects, the present invention provides an ultra-low-cost three mask layers trench MOSFET, comprising:

a plurality of first trenches spaced from each other and extended to a predetermined depth within an epitaxial layer grown on a substrate, wherein each of the first trenches and a region provided between two adjacent first trenches define a single cell;

a second trench extended to a predetermined depth within the epitaxial layer grown on the substrate, provided at an edge of a chip and surrounding cells, wherein the second trench is connected with the first trenches forming an interconnecting trench grids, wherein an open size of each of the first trenches is smaller than that of the second trench;

a trench gate provided within each of the first trenches that is separated by a layer of dielectric material, wherein a top surface of the trench gate is lower than that of the epitaxial layer;

a gate contact region provided within the second trench that is separated by the layer of dielectric material, and connected with the trench gate by conductive polysilicon, wherein a top surface of the gate contact region is lower than that of the epitaxial layer;

a body region provided between two adjacent first trenches and inside the epitaxial layer;

a source region provided at an upper end of the body region;

a third trench penetrating through the source region and extending into the body region, wherein an angle of each of two bottom interior corners of the third trench is bigger than 90-degree and smaller than 180-degree;

a fourth trench extending into the gate contact region, wherein an angle of each of two bottom interior corners of the fourth trench is bigger than 90-degree and smaller than 180-degree; and

a heavy body region provided below the third trench and within the body region, wherein a doping concentration of the heavy body region is higher than that of the body region.

Also, a method of manufacturing an ultra-low-cost three mask layers trench MOSFET, comprising the steps of:

(1) forming an interconnecting trench grids comprising a plurality of first trenches and a second trench spaced from each other and extended to a predetermined depth within an epitaxial layer grown on a substrate, wherein an open size of each of the first trenches is smaller than that of the second trench;

(2) forming a trench gate within each of the first trenches that is separated by a layer of dielectric material, and a gate contact region within the second trench that is separated by the layer of dielectric material, wherein the gate contact region is connected with the trench gate by conductive polysilicon, wherein two top surfaces of the trench gate and the gate contact region are lower than a top surface of the epitaxial layer, respectively;

(3) forming a body region provided between two adjacent first trenches and inside the epitaxial layer;

(4) forming a source region provided at an upper end of the body region;

(5) forming a third trench penetrating through the source region and extending into the body region, and a fourth trench extending into the gate contact region, wherein an angle of each of two bottom interior corners of the third trench is bigger than 90-degree and smaller than 180-degree, an angle of each of two bottom interior corners of the fourth trench is bigger than 90-degree and smaller than 180-degree; and

(6) forming a heavy body region provided below the third trench and within the body region, wherein a doping concentration of the heavy body region is higher than that of the body region.

These and other objectives, features, and advantages of the present invention will become apparent from the following detailed description, the accompanying drawings, and the appended claims.

### BRIEF DESCRIPTION OF THE DRAWINGS

FIGS. 1A to 1E illustrate the fabrication process of a conventional N-channel trench MOSFET device.

FIG. 2 is a cross-sectional view of an ultra-low-cost three mask layers trench MOSFET according to a first preferred embodiment of the present invention.

FIGS. 3A to 3E are a serial of side cross sectional views for showing the processing steps for fabricating an ultra-low-cost three mask layers trench MOSFET as shown in FIG. 2 of the present invention.

FIG. 4 is a cross-sectional view of an ultra-low-cost three mask layers trench MOSFET according to a second preferred embodiment of the present invention.

FIG. 5 is a cross-sectional view of an ultra-low-cost three mask layers trench MOSFET according to a third preferred embodiment of the present invention.

FIG. 6 is a cross-sectional view of an ultra-low-cost three mask layers trench MOSFET according to a fourth preferred embodiment of the present invention.

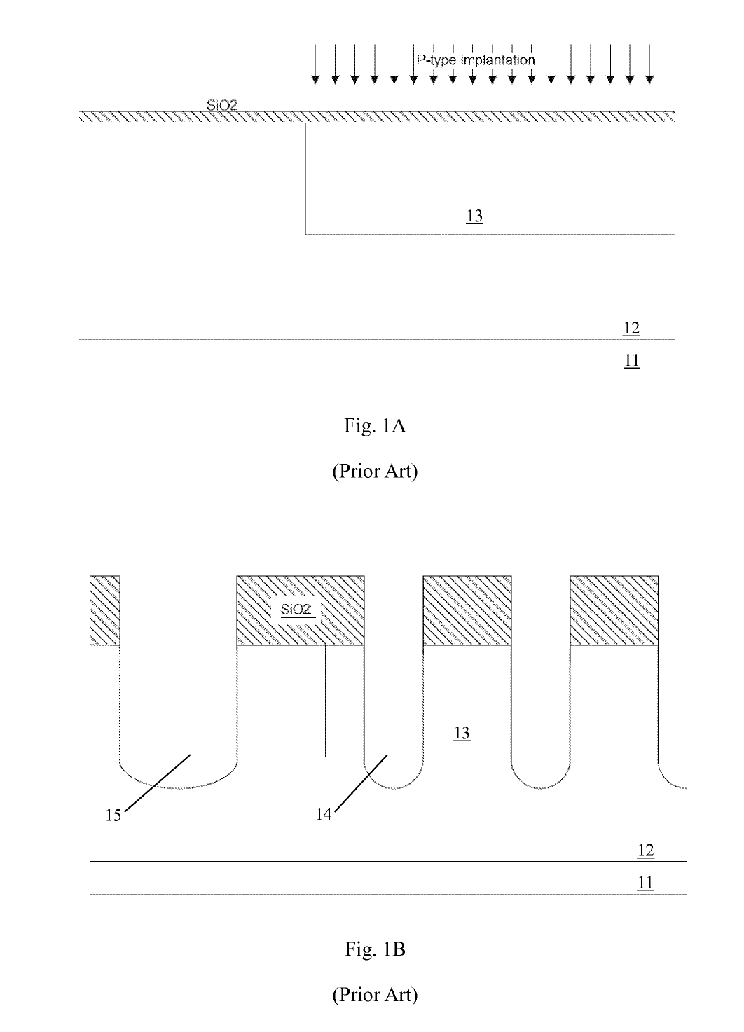

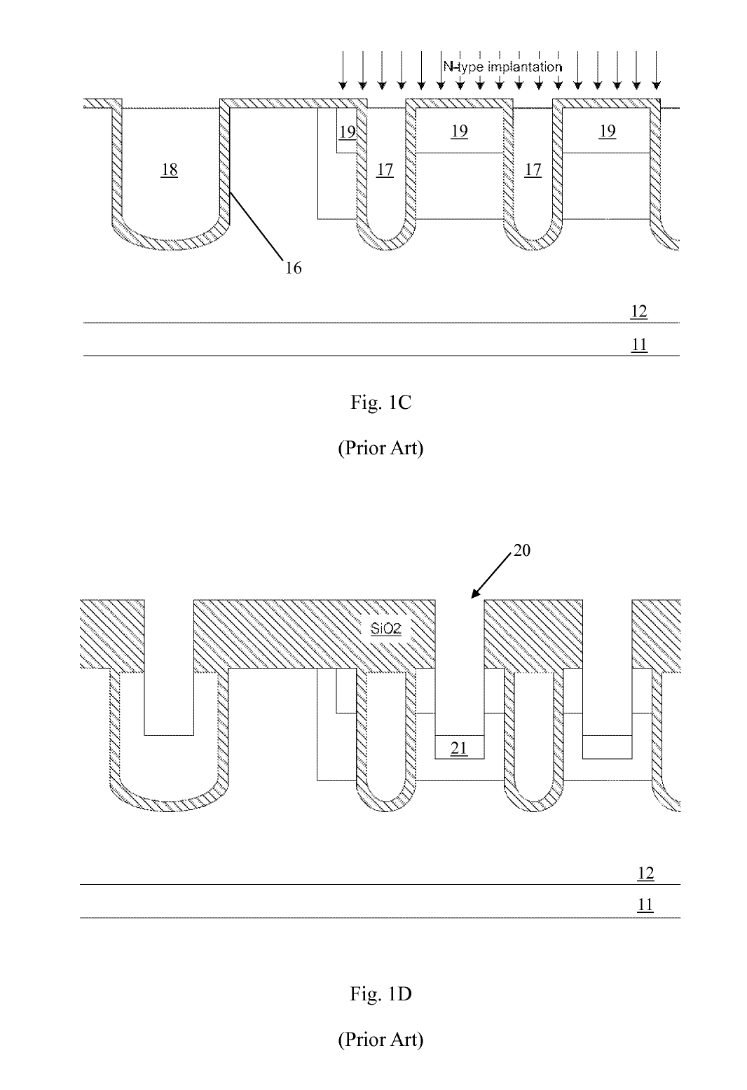

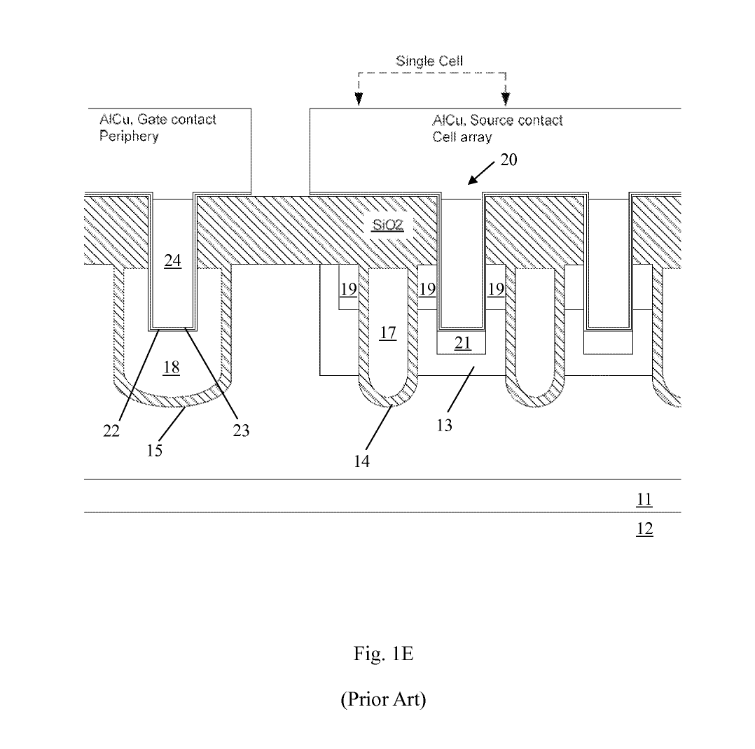

### DETAILED DESCRIPTION OF THE PREFERRED EMBODIMENT

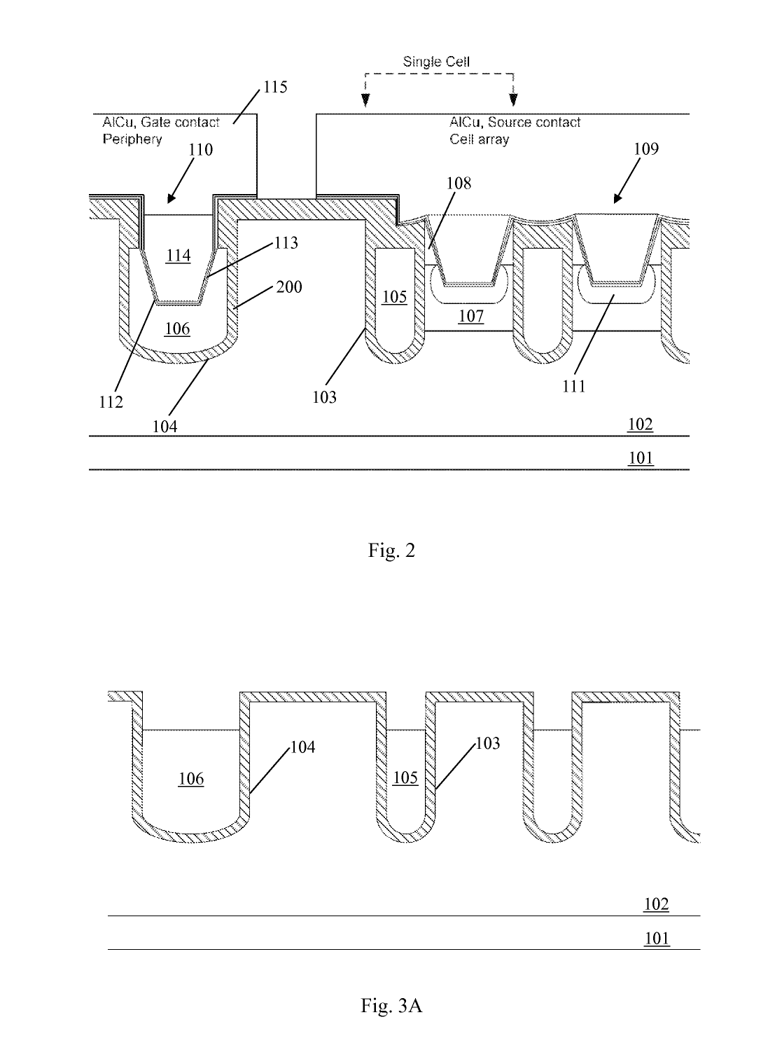

Referring to FIG. 2, an ultra-low-cost three mask layers trench MOSFET according to a first preferred embodiment of the present invention is illustrated. The trench MOSFET is supported on an N+ substrate 101 formed with an N-type epitaxial layer (epi-layer) 102.

The MOSFET comprises a plurality of first trenches 103 and a second trench 104 spaced from each other and extended to a predetermined depth within the N-type epi-layer 102, wherein an open size of each of the first trenches 103 is smaller than that of the second trench 104. A trench gate 105 is deposited within each of the first trenches 103 that is separated by a layer of dielectric material 200. Similarly, a gate contact region 106 is deposited within the second trench 104 that is separated by the layer of dielectric material 200.

A P-body region 107 is provided between two adjacent first trenches 103 and inside the N-type epi-layer 102. An N+ source region 108 is provided at an upper end of the P-body region 107. A third trench 109 penetrates through the N+ source region 108 and extends into the P-body region 107, and a fourth trench 110 extends into the gate contact region 106. It is worth mentioning that the angle of each of two bottom interior corners of the third trench 109 is bigger than 90-degree and smaller than 180-degree, the angle of each of two bottom interior corners of the fourth trench 110 is bigger than 90-degree and smaller than 180-degree. Furthermore, a P+ heavy body region 111 is provided below the third trench 109 and within the P-body region 107.

Moreover, a titanium glue layer 112 is formed on the above structure, and a titanium nitride barrier layer 113 is formed on the titanium glue layer 112. Furthermore, the third trench 109 and the fourth trench 110 can be filled with a tungsten plug 114. A metal layer 115 is deposited on the entire structure.

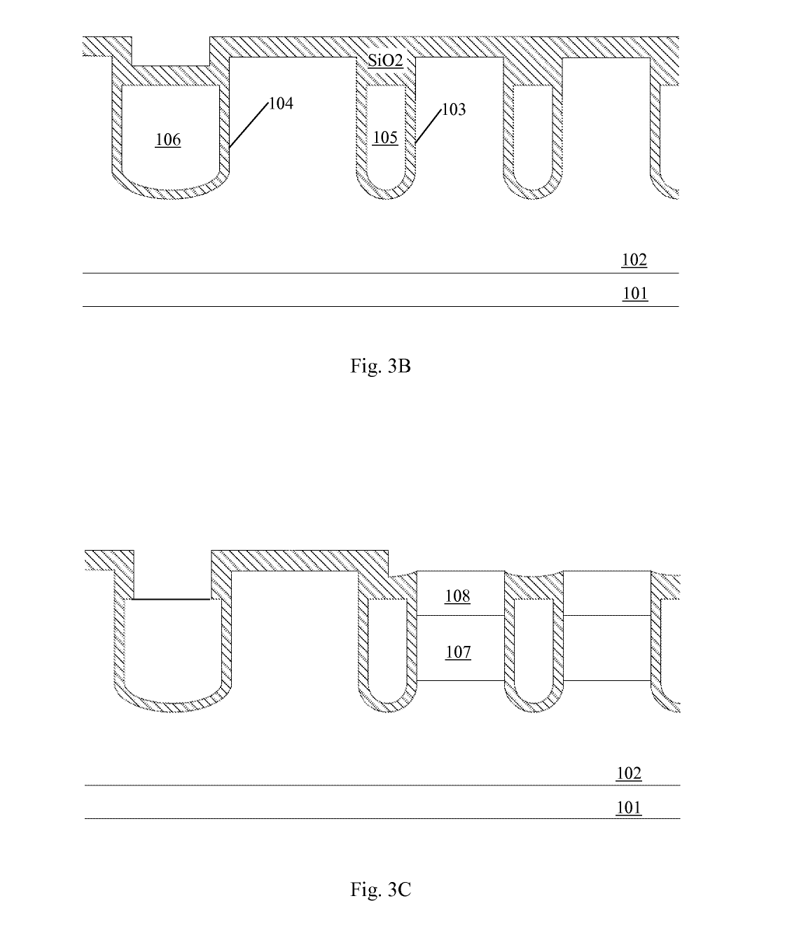

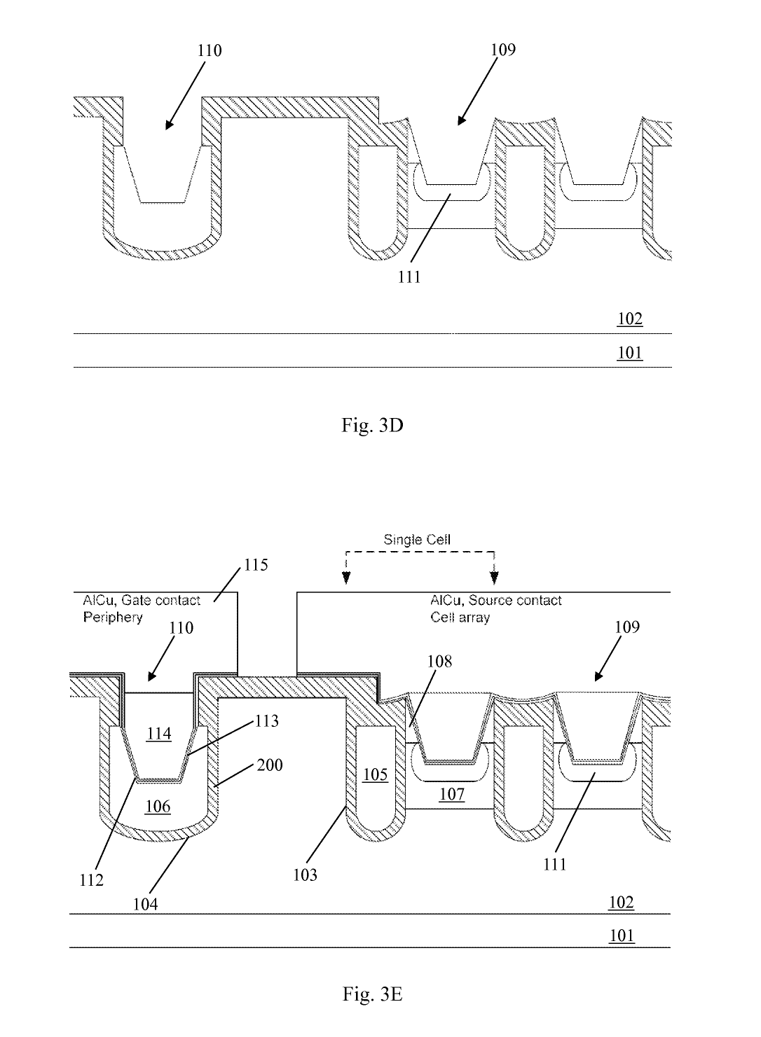

Referring to FIGS. 3A to 3E for a serial of side cross sectional views to illustrate the fabrication steps of an ultra-low-cost three mask layers trench MOSFET as shown in FIG. 2. In FIG. 3A, an N+ substrate 101 is prepared as a drain of the MOSFET, and an N-type epi-layer 102 is grown on the N+ substrate 101. An oxide layer (not shown in FIG. 3A) is grown on the N-type epi-layer 102. Then the 1^{st} mask is used to pattern a plurality of first trenches 103 and a second trench 104 spaced from each other and extended to a predetermined depth within the N-type epi-layer 102, wherein an open size of each of the first trenches 103 is smaller than that of the second trench 104. The first trenches 103 illustrate the MOSFET chip cellular structure gates, each of the first trenches 103 and a region between two adjacent first trenches 103 define a single cell. The second trench 104 is connected with the first trenches 103 forming an interconnecting trench grids, represents a gate contact region. The second trench 104 is on the edge of the chip and surrounds the cells. Posting the oxide layer removed, a gate oxide layer is grown. Then an N+ polysilicon deposition and a dry etch are performed, thereby forming a trench gate 105 within each of the first trenches 103, and a gate contact region 106 within the second trench 104. Two top surfaces of the trench gate 105 and the gate contact region 106 respectively is lower than a top surface of the N-type epi-layer 102.

In FIG. 3B, an oxide layer is uniformly deposited on the entire structure. Because of the different open size, the first trenches 103 for MOSFET gate are fully filled with the oxide layer, while bottom and sidewalls of the second trench 104 for gate contact are covered with the oxide layer, that is to say, a thickness of the oxide layer within each of the first trenches 103 is larger than that of the oxide layer within the second trench 104.

In FIG. 3C, the 2^{nd} mask is used to protect the oxide layer between the gate trench and the gate contact region. Posting a dry etch process, because of the oxide layer thickness difference, the oxide layer on top of the N-type epi-layer 102 among the first trenches 103 and the oxide layer on top of the gate contact region 106 are removed, while the oxide layer inside the first trenches 103 is preserved. Using the remaining oxide layer as hard mask, a P-type implantation followed by a thermal treatment is performed, thereby forming a P-body region 107 between two adjacent first trenches 103. Then an N-type implantation is carried out to form an N+ source region 108 inside the P-body region 107.

In FIG. 3D, a dry etch is performed utilizing the remaining oxide layer as hard mask, thereby forming a third trench 109 penetrating through the N+ source region 108 and extending into the P-body region 107, and a fourth trench 110 extending into the gate contact region 106. The angle of each of two bottom interior corners of the third trench 109 is bigger than 90-degree and smaller than 180-degree, the angle of each of two bottom interior corners of the fourth trench 110 is bigger than 90-degree and smaller than 180-degree. The self-aligned contact formation is completed. A P-type implantation is carried out to reinforce the P-type doping concentration of a region below the third trench 109 and within the P-body region 107, thereby forming a P+ heavy body region 111 below the third trench 109 and within the P-body region 107.

In FIG. 3E, Ti/TiN layers are deposited on the entire structure. Then Tungsten deposition and dry etch are performed to form a tungsten contact plug 114. A metal layer 115 is deposited, and then the 3^{rd} mask is used to pattern the source and gate electrodes. The drain electrode is formed on the rear face of the N+ substrate 101 and not illustrated in the drawings.

It is worth mentioning that the first trenches 103 are used as the gate trenches, the second trench 104 is used as the gate trench for contact, the third trench 109 is used as the source contact trench, and the fourth trench 110 is used as the gate contact trench.

According to the above drawings and descriptions, this invention further discloses a method of manufacturing an ultra-low-cost three mask layers trench MOSFET, comprising the steps of:

(1) forming an interconnecting trench grids comprising a plurality of first trenches and a second trench spaced from each other and extended to a predetermined depth within an epitaxial layer grown on a substrate, wherein an open size of each of the first trenches is smaller than that of the second trench;

(2) forming a trench gate within each of the first trenches that is separated by a layer of dielectric material, and a gate contact region within the second trench that is separated by the layer of dielectric material, wherein the gate contact region is connected with the trench gate by conductive polysilicon, wherein two top surfaces of the trench gate and the gate contact region are lower than a top surface of the epitaxial layer, respectively;

(3) forming a body region provided between two adjacent first trenches and inside the epi-layer;

(4) forming a source region provided at an upper end of the body region;

(5) forming a third trench penetrating through the source region and extending into the body region, and a fourth trench extending into the gate contact region, wherein an angle of each of two bottom interior corners of the third trench is bigger than 90-degree and smaller than 180-degree, an angle of each of two bottom interior corners of the fourth trench is bigger than 90-degree and smaller than 180-degree; and

(6) forming a heavy body region provided below the third trench and within the body region, wherein a doping concentration of the heavy body region is higher than that of the body region.

In the first preferred embodiment, posting a uniform-covering dielectric layer deposition, and then the topography of trenches with different open size is quite different, wherein the smaller open size trench is fully filled, while only bottom and sidewall are covered for the bigger one. After a patterned dry etch process, the bottom of the bigger trench is opened with dielectric spacer left on sidewall, and the smaller one is still filled with dielectric material. The remained dielectric material is used as masks for following N+ source implantation, and/or P-body implantation, and the third and fourth trench etch. A self-aligned source contact process is performed using the remained dielectric material in the trench as hard mask. The limitation coming from source contact trench to gate trench mis-alignment, namely, the third trench to the first trench mis-alignment during photo process is eliminated. Ultra-high density, such as 1 giga cells per square inch could be achieved. So, a novel trench MOSFET structure can be fabricated by only three masks. And at the same time, the much higher cell density, means high device performance, could be achieved.

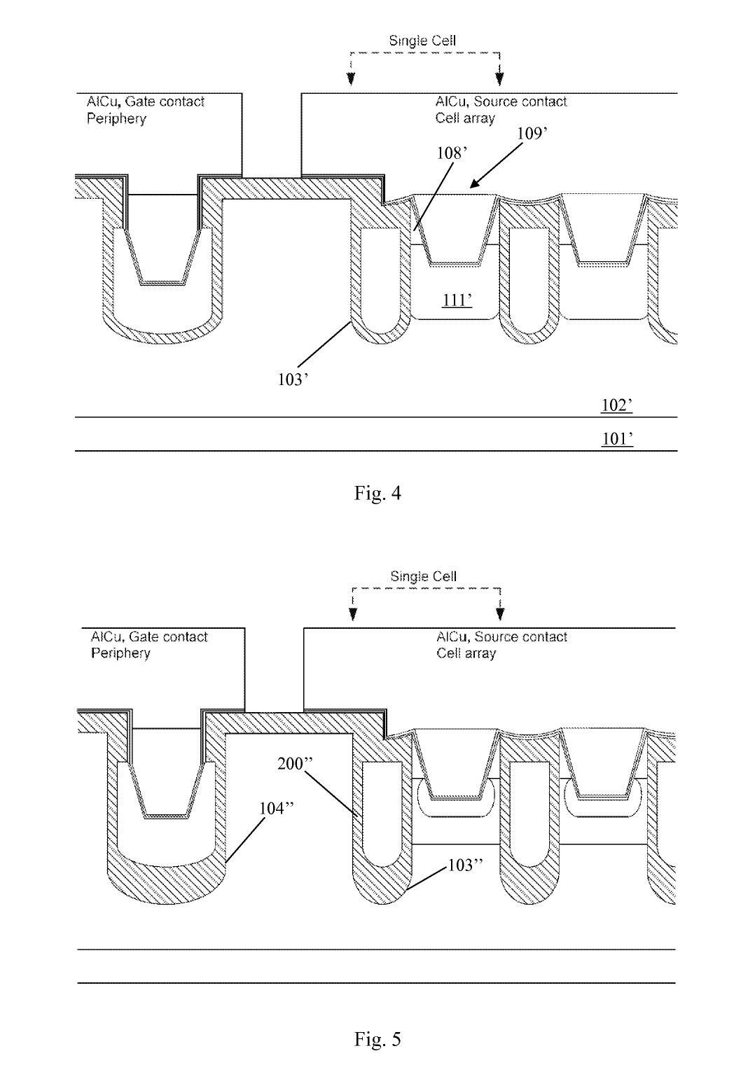

Referring to FIG. 4, an ultra-low-cost three mask layers trench MOSFET according to a second preferred embodiment of the present invention is illustrated. A P+ heavy body region 111′ is provided between two adjacent first trenches 103′ and inside an N-type epi-layer 102′ grown on an N+ substrate 101′. An N+ source region 108′ is provided at an upper end of the P+ heavy body region 111′. A third trench 109′ penetrates through the N+ source region 108′ and extends into the P+ heavy body region 111′. The other structures in the second preferred embodiment are the same as those in the first preferred embodiment.

In the second preferred embodiment, the P-body implantation and thermal process are skipped. Posting a self-aligned contact etch, a P-type implantation and thermal treatment are used, thereby forming the P+ heavy body region 111′ enclosure the third trench 109′, N+ source region 108′, and sidewalls of each of the first trenches 103′.

Referring to FIG. 5, an ultra-low-cost three mask layers trench MOSFET according to a third preferred embodiment of the present invention is illustrated. A layer of thicker gate oxide 200″ is provided at the bottom of each of the first trenches 103″. Similarly, a layer of thicker gate oxide 200″ is provided at the bottom of the second trench 104″. The main benefit of thicker bottom gate oxide is smaller coupled capacitance between the poly gate and the N-type epi-layer (drain), which leads to less switching power loss. And also, the bigger thickness gives better break down performance when facing strong electric field stress when the channel turned off. The other structures in the third preferred embodiment are the same as those in the first preferred embodiment.

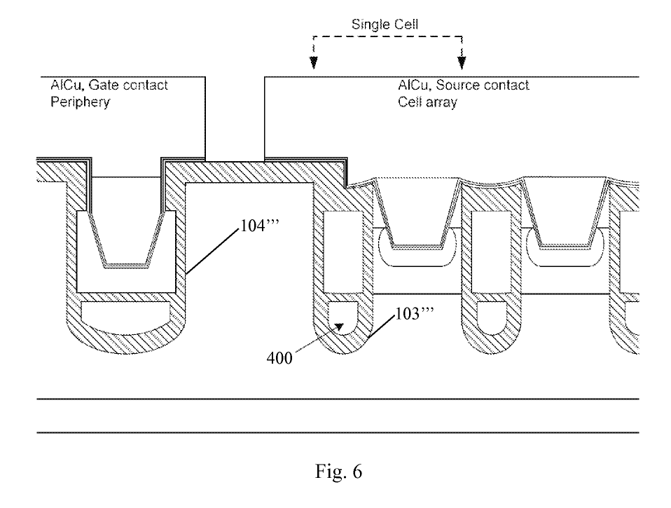

Referring to FIG. 6, an ultra-low-cost three mask layers trench MOSFET according to a fourth preferred embodiment of the present invention is illustrated. The trench MOSFET has a shield poly 400 provided within the oxide layer at a bottom portion of each of the first trenches 103′″. Similarly, the trench MOSFET has a shield poly 400 provided within the oxide layer at a bottom portion of the second trench 104′″. The main benefit of the shield poly 400 is smaller coupled capacitance between the poly gate and the N-type epi-layer (drain), which leads to less switching power loss. The other structures in the fourth preferred embodiment are the same as those in the first preferred embodiment.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. An ultra-low-cost three mask layers trench MOSFET, comprising:
a plurality of first trenches spaced from each other and extended to a predetermined depth within an epitaxial layer grown on a substrate, wherein each of said first trenches and a region provided between two adjacent first trenches define a single cell;
a second trench extended to a predetermined depth within said epitaxial layer grown on said substrate, provided at an edge of a chip and surrounding cells, wherein said second trench is connected with said first trenches forming an interconnecting trench grids, wherein an open size of each of said first trenches is smaller than that of said second trench;
a trench gate provided within each of said first trenches that is separated by a layer of dielectric material, wherein a top surface of said trench gate is lower than that of said epitaxial layer;
a gate contact region provided within said second trench that is separated by said layer of dielectric material, and connected with said trench gate by conductive polysilicon, wherein a top surface of said gate contact region is lower than that of said epitaxial layer;
a body region provided between two adjacent first trenches and inside said epitaxial layer;
a source region provided at an upper end of said body region;
a third trench penetrating through said source region and extending into said body region, wherein an angle of each of two bottom interior corners of said third trench is bigger than 90-degree and smaller than 180-degree;
a fourth trench extending into said gate contact region, wherein an angle of each of two bottom interior corners of said fourth trench is bigger than 90-degree and smaller than 180-degree; and
a heavy body region provided below said third trench and within said body region, wherein a doping concentration of said heavy body region is higher than that of said body region.

2. The ultra-low-cost three mask layers trench MOSFET, as recited in claim 1, further comprising a glue layer and a barrier layer formed on said glue layer, wherein said third trench and fourth trench are filled with a tungsten plug separated from said glue layer by said barrier layer.

3. The ultra-low-cost three mask layers trench MOSFET, as recited in claim 1, wherein a thickness of a bottom of said layer of dielectric material is bigger than that of a sidewall of said layer of dielectric material.

4. The ultra-low-cost three mask layers trench MOSFET, as recited in claim 2, wherein a thickness of a bottom of said layer of dielectric material is bigger than that of a sidewall of said layer of dielectric material.

5. The ultra-low-cost three mask layers trench MOSFET, as recited in claim 1, further comprising a shield poly provided within said layer of dielectric material at a bottom portion of each of said first trenches and second trench.

6. The ultra-low-cost three mask layers trench MOSFET, as recited in claim 2, further comprising a shield poly provided within said layer of dielectric material at a bottom portion of each of said first trenches and second trench.

7. An ultra-low-cost three mask layers trench MOSFET, comprising:
a plurality of first trenches spaced from each other and extended to a predetermined depth within an epitaxial layer grown on a substrate, wherein each of said first trenches and a region provided between two adjacent first trenches define a single cell;
a second trench extended to a predetermined depth within said epitaxial layer grown on said substrate, provided at an edge of a chip and surrounding cells, wherein said second trench is connected with said first trenches forming an interconnecting trench grids, wherein an open size of each of said first trenches is smaller than that of said second trench;
a trench gate provided within each of said first trenches that is separated by a layer of dielectric material, wherein a top surface of said trench gate is lower than that of said epitaxial layer;
a gate contact region provided within said second trench that is separated by said layer of dielectric material, and connected with said trench gate by conductive polysilicon, wherein a top surface of said gate contact region is lower than that of said epitaxial layer;
a heavy body region provided between two adjacent first trenches and inside said epitaxial layer;
a source region provided at an upper end of said heavy body region;
a third trench penetrating through said source region and extending into said heavy body region, wherein an angle of each of two bottom interior corners of said third trench is bigger than 90-degree and smaller than 180-degree; and
a fourth trench extending into said gate contact region, wherein an angle of each of two bottom interior corner of said fourth trench is bigger than 90-degree and smaller than 180-degree.

8. The ultra-low-cost three mask layers trench MOSFET, as recited in claim 7, further comprising a glue layer and a barrier layer formed on said glue layer, wherein said third trench and fourth trench are filled with a tungsten plug separated from said glue layer by said barrier layer.

9. The ultra-low-cost three mask layers trench MOSFET, as recited in claim 7, wherein a thickness of a bottom of said layer of dielectric material is bigger than that of a sidewall of said layer of dielectric material.

10. The ultra-low-cost three mask layers trench MOSFET, as recited in claim 8, wherein a thickness of a bottom of said layer of dielectric material is bigger than that of a sidewall of said layer of dielectric material.

11. The ultra-low-cost three mask layers trench MOSFET, as recited in claim 7, further comprising a shield poly provided within said layer of dielectric material at a bottom portion of each of said first trenches and second trench.

12. The ultra-low-cost three mask layers trench MOSFET, as recited in claim 8, further comprising a shield poly provided within said layer of dielectric material at a bottom portion of each of said first trenches and second trench.

13. A method of manufacturing an ultra-low-cost three mask layers trench MOSFET, comprising the steps of:
(1) forming an interconnecting trench grids comprising a plurality of first trenches and a second trench spaced from each other and extended to a predetermined depth within an epitaxial layer grown on a substrate, wherein an open size of each of the first trenches is smaller than that of the second trench;
(2) forming a trench gate within each of the first trenches that is separated by a layer of dielectric material, and a gate contact region within the second trench that is separated by the layer of dielectric material, wherein the gate contact region is connected with the trench gate by conductive polysilicon, wherein two top surfaces of the trench gate and the gate contact region are lower than a top surface of the epitaxial layer, respectively;
(3) forming a body region provided between two adjacent first trenches and inside the epi-layer;
(4) forming a source region provided at an upper end of the body region;
(5) forming a third trench penetrating through the source region and extending into the body region, and a fourth trench extending into the gate contact region, wherein an angle of each of two bottom interior corners of the third trench is bigger than 90-degree and smaller than 180-degree, an angle of each of two bottom interior corners of the fourth trench is bigger than 90-degree and smaller than 180-degree; and
(6) forming a heavy body region provided below the third trench and within the body region, wherein a doping concentration of the heavy body region is higher than that of the body region.

14. The method, as recited in claim 13, further comprising the step of forming a glue layer and a barrier layer formed on the glue layer, wherein the third trench and fourth trench are filled with a tungsten plug separated from the glue layer by the barrier layer.

15. The method, as recited in claim 13, wherein a thickness of a bottom of the layer of dielectric material is bigger than that of a sidewall of the layer of dielectric material.

16. The method, as recited in claim 13, further comprising the step of forming a shield poly provided within the layer of dielectric material at a bottom portion of each of the first trenches and second trench.

17. A method of manufacturing an ultra-low-cost three mask layers trench MOSFET, comprising the steps of:
(1) forming an interconnecting trench grids comprising a plurality of first trenches and a second trench spaced from each other and extended to a predetermined depth within an epitaxial layer grown on a substrate, wherein an open size of each of the first trenches is smaller than that of the second trench;
(2) forming a trench gate within each of the first trenches that is separated by a layer of dielectric material, and a gate contact region within the second trench that is separated by the layer of dielectric material, wherein the gate contact region is connected with the trench gate by conductive polysilicon, wherein two top surfaces of the trench gate and the gate contact region are lower than a top surface of the epitaxial layer, respectively;
(3) forming a source region provided at an upper end of the epitaxial layer between two adjacent first trenches;
(4) forming a third trench penetrating through the source region, and a fourth trench extending into the gate contact region, wherein an angle of each of two bottom interior corners of the third trench is bigger than 90-degree and smaller than 180-degree, an angle of each of two bottom interior corners of the fourth trench is bigger than 90-degree and smaller than 180-degree; and
(5) forming a heavy body region provided between two adjacent first trenches, below the third trench and inside the epi-layer, so that the heavy body region encloses the third trench, the source region, and sidewalls of each of the first trenches.

18. The method, as recited in claim 17, further comprising the step of forming a glue layer and a barrier layer formed on the glue layer, wherein the third trench and fourth trench are filled with a tungsten plug separated from the glue layer by the barrier layer.

19. The method, as recited in claim 17, wherein a thickness of a bottom of the layer of dielectric material is bigger than that of a sidewall of the layer of dielectric material.

20. The method, as recited in claim 17, further comprising the step of forming a shield poly provided within the layer of dielectric material at a bottom portion of each of the first trenches and second trench.
